(19) United States
(12) Patent Application Publication
(10) Pub. No.: US 2022/0187687 A1
(43) Pub. Date: Jun. 16, 2022

(54) Module Design for Enhanced Radiometric Calibration of Thermal Camera

(71) Applicant: Waymo LLC, Mountain View, CA (US)

(72) Inventors: Shashank Sharma, Mountain View, CA (US); Matthew Last, San Jose, CA (US); Ralph Shepard, Menlo Park, CA (US)

(21) Appl. No.: 17/117,534

(22) Filed: Dec. 10, 2020

(51) Int. Cl. G03B 17/55; H05K 1/02; H04N 5/232; H04N 5/225

(52) U.S. Cl. CPC G03B 17/55; H05K 1/028; H05K 1/0212; B60R 11/04; H04N 5/2252; H04N 5/22521; H05K 2201/10151; H04N 5/23229

(57) ABSTRACT

The present disclosure relates to optical systems, vehicles, and methods for providing improved thermal images. An example optical system includes a housing, a thermal camera disposed inside the housing, and an optical window coupled to an opening of the housing. The optical system also includes a heater assembly. The heater assembly includes a window heater and at least one connector extending from the window heater. The window heater is thermally coupled to an inner surface of the optical window. The window heater is configured to maintain the optical window at a desired temperature.

### BACKGROUND

Self-driving vehicles can utilize multiple sensors to obtain information about the external environment for route planning, perception, and navigation. In some embodiments, such sensors can include infrared thermal cameras.

### SUMMARY

The present disclosure relates to optical systems and methods for their use that may provide improved infrared sensing capabilities. In some examples, such optical systems could be configured to be utilized with self-driving vehicles for improved detection and disambiguation of objects in their respective environments.

In a first aspect, an optical system is provided. The optical system includes a housing and a thermal camera disposed inside the housing. The optical system also includes an optical window coupled to an opening of the housing. The optical system additionally includes a heater assembly. The heater assembly includes a window heater and at least one connector extending from the window heater. The window heater is thermally coupled to an inner surface of the optical window. The window heater is configured to maintain the optical window at a desired temperature.

In a second aspect, a method is provided. The method includes receiving, from at least one window temperature sensor, information indicative of a temperature of an optical window that is optically coupled to a thermal camera. The method additionally includes receiving at least one thermal image from the thermal camera. The method also includes determining a radiometric offset based on the temperature of the optical window. The method yet further includes adjusting the at least one thermal image based on the radiometric offset so as to provide at least one adjusted thermal image.

Other aspects, embodiments, and implementations will become apparent to those of ordinary skill in the art by reading the following detailed description, with reference where appropriate to the accompanying drawings.

### BRIEF DESCRIPTION OF THE FIGURES

FIG. 1 illustrates an optical system, according to an example embodiment.

FIG. 2A illustrates the optical system of FIG. 1, according to an example embodiment.

FIG. 2B illustrates the optical system of FIG. 1, according to an example embodiment.

FIG. 2C illustrates the optical system of FIG. 1, according to an example embodiment.

FIG. 3A illustrates a portion of the optical system of FIG. 1, according to an example embodiment.

FIG. 3A illustrates a portion of the optical system of FIG. 1, according to an example embodiment.

FIG. 3B illustrates several views of a portion of the optical system of FIG. 1, according to an example embodiment.

FIG. 4A illustrates several views of a portion of the optical system of FIG. 1, according to an example embodiment.

FIG. 4B illustrates the optical system of FIG. 1, according to an example embodiment.

FIG. 4C illustrates the optical system of FIG. 1, according to an example embodiment.

FIG. 4D illustrates a portion of the optical system of FIG. 1, according to an example embodiment.

FIG. 4E illustrates a portion of the optical system of FIG. 1, according to an example embodiment.

FIG. 4F illustrates a portion of the optical system of FIG. 1, according to an example embodiment.

FIG. 4G illustrates several views of a portion of the optical system of FIG. 1, according to an example embodiment.

FIG. 5A illustrates a vehicle, according to an example embodiment.

FIG. 5B illustrates a vehicle, according to an example embodiment.

FIG. 5C illustrates a vehicle, according to an example embodiment.

FIG. 5D illustrates a vehicle, according to an example embodiment.

FIG. 5E illustrates a vehicle, according to an example embodiment.

FIG. 6 illustrates a method, according to an example embodiment.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features. Other embodiments can be utilized, and other changes can be made, without departing from the scope of the subject matter presented herein.

Thus, the example embodiments described herein are not meant to be limiting. Aspects of the present disclosure, as generally described herein, and illustrated in the figures, can be arranged, substituted, combined, separated, and designed in a wide variety of different configurations, all of which are contemplated herein.

Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

### I. Overview

One or more infrared cameras could be utilized to capture images of infrared light (e.g., light with wavelengths between 1 micron to about 14 microns) from an environment around an autonomous vehicle. Infrared cameras may be able to readily image objects that reflect and/or emit infrared light, such as objects that have a temperature higher than the ambient environment.

Systems and methods described herein could improve radiometric calibration of infrared thermal camera systems in several ways.

First, an infrared camera may include a Si/Ge optical window and a flexible heater with good thermal contact to the window. In some scenarios, environmental factors such as wind, rain, snow, ice, etc. could form temporary cold spots and/or an unequal temperature distribution along the optical window. The heater could be configured to maintain the entire window at a desired temperature. In such scenarios, the heater could be coupled to a controller by way of a flexible connection (e.g., a polyimide flex cable material). In some embodiments, a window temperature sensor could be located along the flexible connection. Such sensor placement could reduce potential errors in the control loop and/or reduce or eliminate actual temperature differences between the heater and the window temperature sensor. The material of the flexible connection could include a thermally-insulating material to avoid heat conducting away from the optical window by way of the flexible connection. In various examples, the flexible connection could include one or more temperature sensors and/or one or more humidity sensors.

In some examples, the optical window and/or other elements of the optical system could be formed from silicon and/or germanium. Other materials that substantially transmit infrared light (e.g., long-wavelength infrared LWIR light) are possible and contemplated. Light with wavelength around 10 microns (μm) is often important for self-driving vehicles trying to detect important objects near the vehicle (e.g., pedestrians or wild animals) during night time and bad weather. In various examples, the window could be configured to be able to survive rock strikes (e.g., to an impact protection rating of IK07). In various embodiments, IK07 could include protection against 2 joules of impact (the equivalent to the impact of a 0.5 kg mass dropped from 400 mm above the impacted surface). Si and Ge are fracture sensitive materials and increasing thickness leads to significant loss in transmission (performance hit) and increase in sensor module cost.

In example embodiments, the window temperature sensor could be configured to measure the temperature of the optical window. In such a scenario, the heated window could produce thermal radiation that could produce a DC offset in image brightness. Such an offset could be subtracted from the overall image if the window temperature is known and uniform across the field of view.

In various examples, a heater controller could be dynamically adjusted to maintain the optical window at a set temperature (e.g., 50° C.) and/or to exceed a dew point by a buffer temperature such as 5° C. to avoid condensation on the circuitry. Additionally, the heater controller could be configured to reduce the temperature of the optical window in case of potential thermal runaway due to faulty hardware or software.

In further embodiments, a thermal baffle, which could be made from plastic, may include a heater connection that preloads the heater against the optical window and provides a high thermal resistance path. In such a scenario, most of the heat from the heater could be configured to be conducted through the window and not into other components of the system. The baffle could also reduce the amount of stray light that impinges onto the image sensor of the thermal camera. For example, the baffle could prevent a direct line of sight between the optical lens and the heater.

Yet further, in some examples, the thermal camera could include an air temperature and/or humidity sensor. Such sensors could help calculate a dew point for air inside the optical system housing. Controlling a temperature of the optical window and/or the interior of the optical system could reduce or eliminate condensation on the optical element and/or inside the optical system housing. Furthermore, such sensors could provide radiometric calibration and/or correction terms for air humidity, temperature of external air. In some embodiments, the optical system could include a Gore vent.

In some examples, the thermal camera could include a further temperature sensor that is thermally coupled to one or more lenses of the system. In such scenarios, the lens could be disposed in front of an image sensor. In example embodiments, the heat of the lens could act as a noise source. For example, lenses may heat up due to heat transfer at least in part from conduction to air in the camera module, radiation from the window itself, and/or conduction from electronics and image sensor. In such scenarios, measuring the lens temperature is useful and can be corrected based on systems and methods described herein.

In various embodiments, the thermal camera may include a housing. The housing could include a material (e.g., plastic) to thermally isolate the heated window from the sensor. In such scenarios, the back housing could be formed from metal and may include fins to help remove heat from electronics to an external environment.

### II. Example Optical Systems

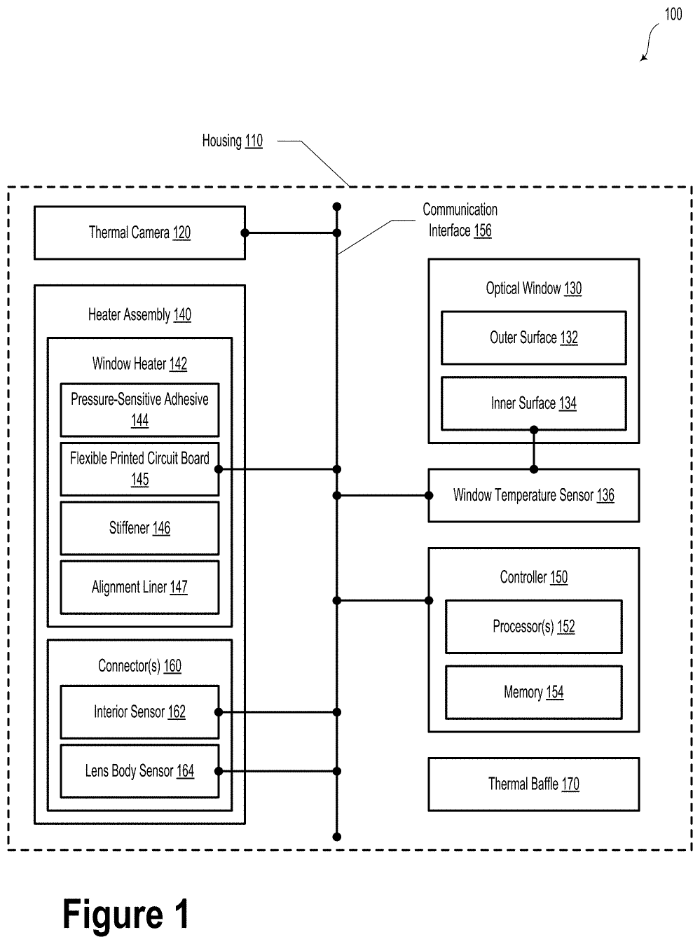

FIG. 1 illustrates an optical system 100, according to an example embodiment. In some examples, the optical system 100 could include a camera system for capturing images of a scene. In specific embodiments, the optical system 100 could provide imaging functionality for a self-driving vehicle, a robot, or another type of vehicle configured to navigate its environment. Additionally or alternatively, the optical system 100 could be a thermal camera system that could be utilized for machine vision applications, such as in image sensors for autonomous and/or semi-autonomous vehicles.

The optical system 100 includes a housing 110. The housing 110 could include an enclosure that could house some or all of the other elements of the optical system 100. In some examples, the housing 110 could be formed from glass, plastic, and/or metal. Other materials are possible and contemplated.

The optical system 100 also includes a thermal camera 120 that is disposed inside the housing 110. In such scenarios, the thermal camera 120 could be a thermal infrared camera (e.g., a thermographic imager). In such scenarios, the thermal infrared camera could form images of a field of view of an environment of the thermal camera 120 using infrared light. In some embodiments, the thermal camera 120 could be sensitive to wavelengths from approximately 1 micron to 14 microns. However, other wavelengths and wavelength ranges are possible and contemplated.

The optical system 100 additionally includes an optical window 130 that is coupled to an opening of the housing 110. In some embodiments, the optical window 130 could include at least one of: germanium or silicon. Other infrared-transmissive materials are possible and contemplated. In some examples, the thermal camera 120 could configured to capture images of an external environment by way of the optical window 130. In further examples, an outer surface 132 of the optical window 130 could be disposed such that it is substantially flush with an outer surface of the housing 110. Such embodiments may provide improved ease of cleaning and/or maintenance of the optical system 100.

The optical system 100 also includes a heater assembly 140. The heater assembly 140 includes a window heater 142 and at least one connector 160. The at least one connector 160 could extend from the window heater 142. The window heater 142 is thermally coupled to an inner surface 134 of the optical window 130. The window heater 142 could be configured to maintain the optical window 130 at a desired temperature.

In some examples, the window heater 142 could be arranged in a multi-layer stack. For example, the multi-layer stack could include a pressure-sensitive adhesive (PSA) 144, a two-layer flexible printed circuit board (flex PCB) 145, and a stiffener 146. Additionally or alternatively, at least one of the PSA 144 or the stiffener 146 could include a thermally-conductive material (e.g., a metal).

As described herein, the flex PCB 145 could include at least one heater element and at least one window temperature sensor 136.

In some examples, the stiffener 146 includes at least one of: stainless steel, aluminum, or copper. Other materials that are mechanically stiff and/or resistant to deformation are contemplated and possible.

In various examples, the optical system 100 could additionally include a thermal baffle 170. In such scenarios, the thermal baffle 170 could be configured to define a field of view of the thermal camera 120 such that the window heater 142 is not within the field of view of the thermal camera. For example, the thermal baffle 170 could include a thermally-insulating material (e.g., plastic, rubber, ceramic).

In some embodiments, the thermal baffle 170 could include one or more protrusions that could limit the field of view of the thermal camera 120 and prevent light (infrared or otherwise) from impinging onto the thermal camera 120. In some embodiments, the thermal baffle 170 could be maintained at a desired temperature so as to reduce or minimize stray thermal noise in the thermal camera 120. Put another way, the thermal baffle 170 could be shaped and/or positioned so as to prevent at least a portion of the thermal radiation emitted from the window heater 142 from being detected within a line of sight and/or field of view of the thermal camera 120.

In some examples, the window heater 142 could include a flat annulus shape having a first surface coupled to the optical window 130 and a second surface coupled to the thermal baffle 170. Additionally or alternatively, the window heater 142 could be shaped as a flat circular ring or flat rectangular ring. In some embodiments, the window heater 142 could also include an alignment liner 147. In such scenarios, the alignment liner 147 could be configured to assist in the alignment of the window heater 142 with respect to the optical window 130 and/or the thermal baffle 170.

In various examples, the heater assembly 140 could include a flexible material. For example, the flexible material could include at least one of: polyimide, polyester, polyether ether ketone (PEEK), or flexible silicon. In some embodiments, the flexible material could enable the heater assembly 140 to be more easily routed around and among other elements within the housing 110. In some examples, the heater assembly 140 could include a window heater 142 that incorporated into and/or disposed on a flexible substrate material, such as silicone rubber or polyimide.

In some examples, the at least one connector 160 includes a first connector having an interior sensor 162. In such scenarios, the interior sensor 162 is disposed within an interior cavity or region of the housing 110. Furthermore, the interior sensor 162 could be configured to provide information indicative of a temperature and a humidity of the interior cavity or region of the housing 110.

In some examples, the at least one connector 160 could additionally or alternatively include a second connector having a lens body sensor 164. In such scenarios, the lens body sensor 164 is thermally coupled to a lens body of the thermal camera 120 by way of a thermal interface material. As such, the lens body sensor 164 could be configured to provide information indicative of a temperature of the lens body and/or other elements of the thermal camera 120.

In an example embodiment, the interior sensor 162 and/or the lens body sensor 164 could be configured to detect a temperature (e.g., between −20° C. and 60° C. with 0.1° C. resolution) of various components and/or spaces within the housing 110. For example, the interior sensor 162 could be configured to provide information indicative of a current temperature of the thermal camera 120 and/or the optical window 130. The interior sensor 162 and/or the lens body sensor 164 could be configured to provide information indicative of a humidity (e.g., between 5% and 95% humidity with 1% resolution) of various regions inside or outside the housing 110. For example, the interior sensor 162 and/or the lens body sensor 164 could be configured to determine a concentration of water vapor present inside the housing 110.

In some embodiments, the optical system 100 includes a controller 150. The controller 150 includes at least one processor 152 and a memory 154. In some embodiments, the controller 150 could be communicatively coupled (e.g., wirelessly or wired) to various elements of optical system 100 by way of communication interface 156. For example, the controller 150 could be communicatively coupled to the thermal camera 120, the interior sensor 162, and the window heater 142 in a wired or wireless manner by way of the communication interface 156.

The at least one processor 152 is configured to execute instructions stored in the memory 154 so as to carry out operations. The operations could include receiving, from at least one window temperature sensor 136, information indicative of a temperature of the optical window 130.

In various examples, the operations could also include receiving at least one thermal image from the thermal camera 120.

In some embodiments, the operations may also include determining a radiometric offset based on the temperature of the optical window 130.

Additionally or alternatively, the operations may also include adjusting the at least one thermal image based on the radiometric offset so as to provide at least one adjusted thermal image.

As an example, the operations could include determining, based on the temperature of the optical window 130, a temperature gradient of the optical window 130. In such scenarios, determining the radiometric offset could be further based on the temperature gradient of the optical window 130.

In various embodiments, the operations could also include causing the window heater 142 to adjust the temperature of the optical window 130 according to a desired window temperature.

In some embodiments, determining the radiometric offset could be further based on at least one of: an interior cavity temperature of the housing 110, an interior cavity humidity of the housing 110, or a lens body temperature of the thermal camera 120. It will be understood that the radiometric offset could be based on other factors, such as an ambient temperature, a material of the optical window 130, an image sensor type of the thermal camera 120, and/or other factors.

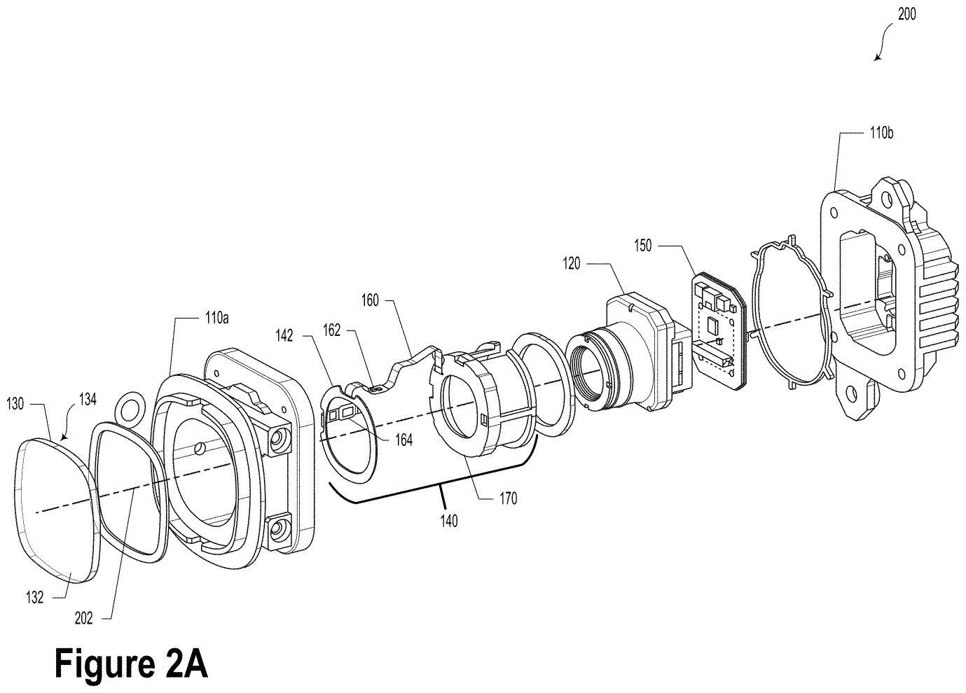

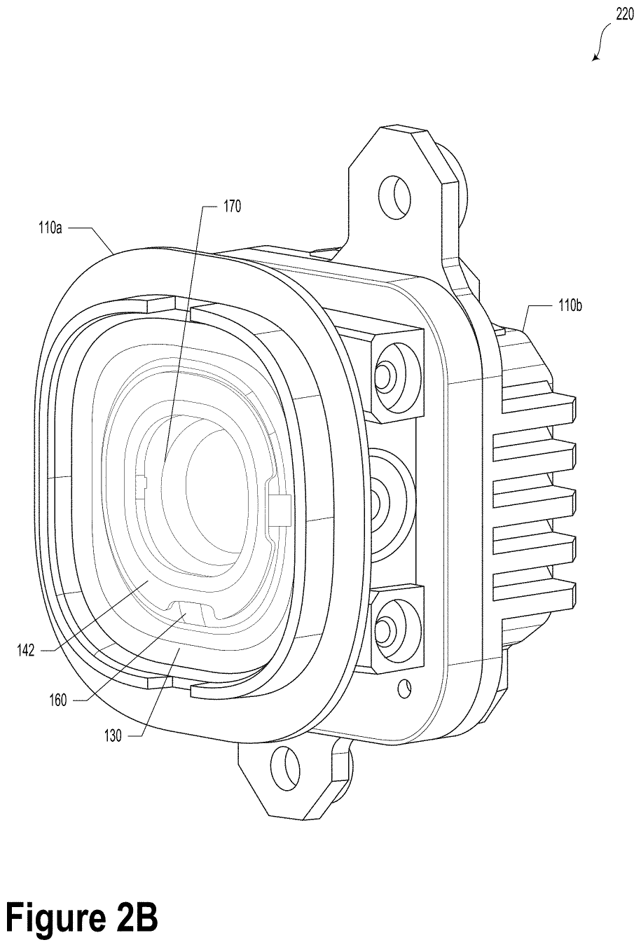

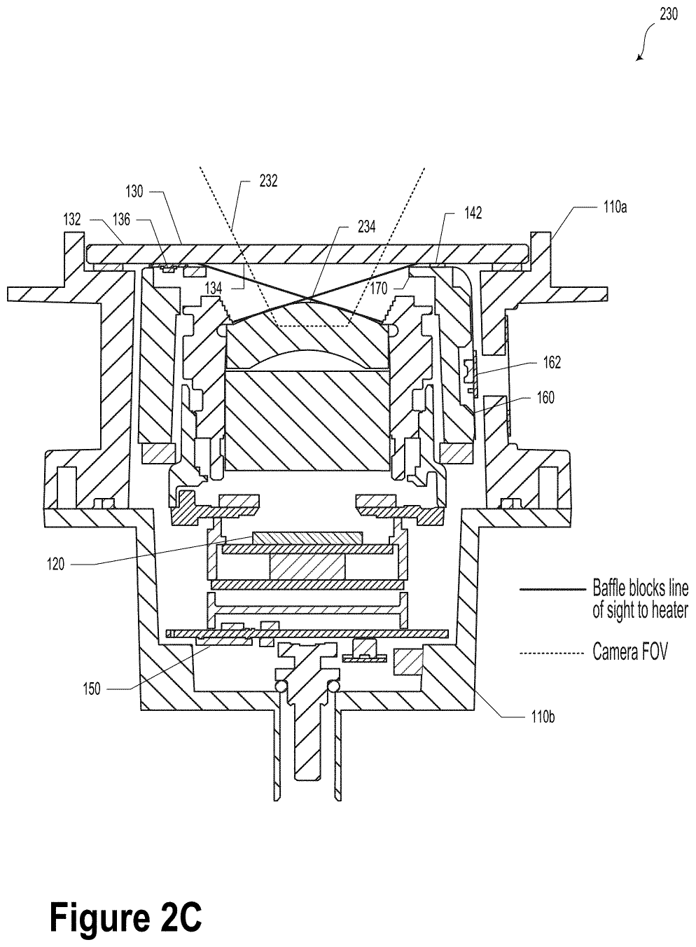

FIG. 2A illustrates the optical system 100 of FIG. 1, according to an example embodiment. FIG. 2A provides an “exploded” view 200 of the optical system 100 where various components of optical system 100 have been exploded along an optical axis 202. As illustrated in FIG. 2A, optical system 100 could include an optical window 130 that may couple to and/or seat into a first housing portion 110a. The window heater 142 may be thermally and physically coupled to an inner surface 134 of the optical window 130. The window heater 142 could be coupled to a connector 160 that may include an interior sensor 162 and a lens body sensor 164. Thermal camera 120 could be coupled to controller 150.

Thermal baffle 170 could include a metal or ceramic element configured to block or mask the window heater 142 from being within a field of view of the thermal camera 120. In some embodiments, the thermal baffle 170 could prevent and/or reduce blackbody light emission from the window heater 142 from reaching the thermal camera 120. The optical system 100 could include a second housing portion 110b. While FIG. 2A provides an example illustration, it will be understood that other arrangements, stack-ups, and/or elements are possible and contemplated within the context of the present disclosure.

FIG. 2B illustrates the optical system 100 of FIG. 1, according to an example embodiment. As illustrated, FIG. 2B shows an oblique angle view 220 of the optical system 100. While FIG. 2B provides an example illustration of optical system 100, it will be understood that other arrangements, stack-ups, and/or elements are possible and contemplated within the context of the present disclosure.

FIG. 2C illustrates the optical system 100 of FIG. 1, according to an example embodiment. As illustrated, FIG. 2C shows a cross-sectional view 230 of the optical system 100. While FIG. 2C provides an example illustration of optical system 100, it will be understood that other arrangements, stack-ups, and/or elements are possible and contemplated within the context of the present disclosure.

As illustrated in FIG. 2C, the thermal baffle 170 could block the line of sight between the thermal camera 120 and the window heater 142. In such a scenario, the thermal baffle 170 may desirably reduce an amount of blackbody radiation emitted the window heater 142 from being detected by the thermal camera 120. Put another way, the field of view 232, which could be formed in part by optical element 234, may be configured and/or limited by the thermal baffle 170 so as to not include the light emitted by the window heater 142.

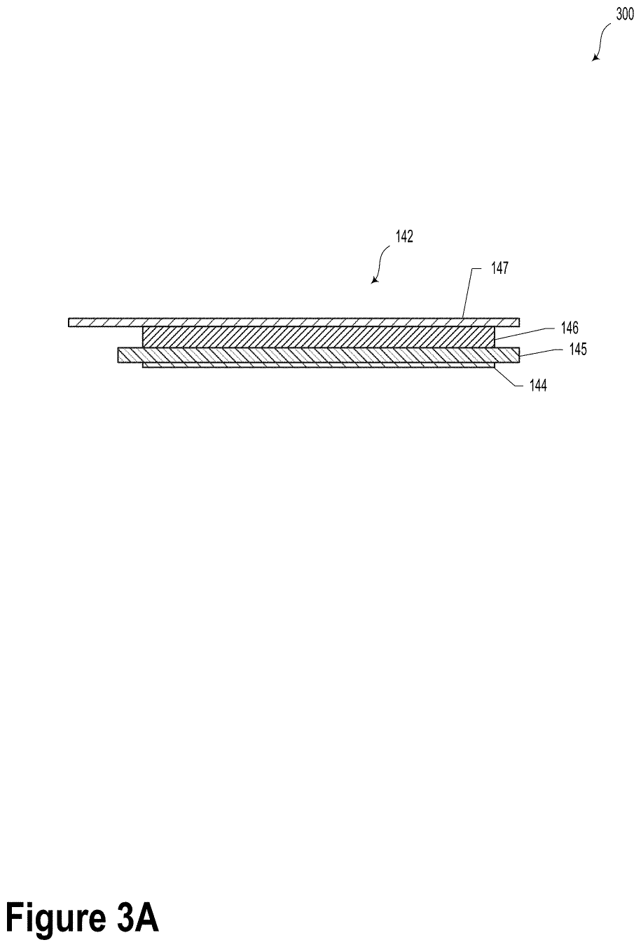

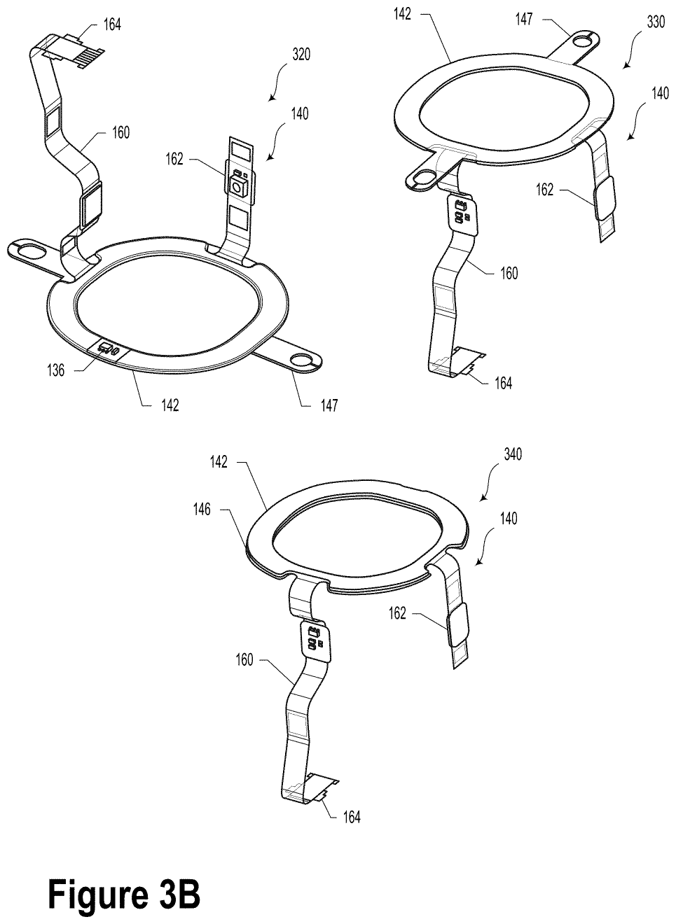

FIG. 3A illustrates a cross-sectional view 300 of a portion of optical system 100 of FIG. 1, according to an example embodiment. As illustrated, the window heater 142 could include a multi-layer stack arrangement that includes a pressure-sensitive adhesive 144, a flexible printed circuit board 145, a stiffener 146, and an alignment liner 147.

In some examples, the pressure-sensitive adhesive 144 could be utilized to adhere the window heater 142 to the inner surface 134 of the optical window 130. Additionally or alternatively, the pressure-sensitive adhesive 144 could adhere to the housing 110 and/or another structure of the optical system 100. The pressure-sensitive adhesive 144 layer could include a liner with a pull tab to protect the layer during shipping and/or storage.

The flexible printed circuit board 145 could include a two-sided flexible circuit. In some examples, the flexible printed circuit board 145 could include a thin insulating polymer film having patterned conductive traces and circuit elements on one or both surfaces. In some examples, the flexible printed circuit board 145 could include a thin polymer coating to protect the conductive traces and circuit elements. In some embodiments, the flexible printed circuit board 145 could include various material including bare copper, tin-plated copper, acrylic, pressure sensitive adhesives, polyester, among other possibilities.

In some examples, the stiffener 146 could include a thin layer (e.g., 150-300 micron thickness) of stainless steel that may be laminated to provide varying levels of rigidity or flexibility.

The disposable alignment liner 147 could be formed from plastic or paper and a low tack adhesive. The low tack adhesive could provide that the window heater 142 could be easily repositioned, realigned, and/or removed. In some embodiments, the disposable alignment layer 147 could be utilized to align the window heater 142 in a holder (e.g., a jig) before attaching the window heater 142 to the optical window 130. Once the parts are joined/attached, the disposable alignment layer 147 could be removed and/or disposed of.

As illustrated in FIG. 3A, the stiffener 146 could be disposed between the flexible printed circuit board 145 and the disposable alignment liner 147. However, alternative arrangements and stack-ups are possible and contemplated.

FIG. 3B illustrates several views 320, 330, and 340 of a heater assembly 140 of the optical system 100 of FIG. 1, according to an example embodiment. Views 320, 330, and 340 illustrate various arrangements of interior sensor 162, lens body sensor 164, and/or connector 160. It will be understood that other arrangements of the elements of the heater assembly 140 are possible and contemplated.

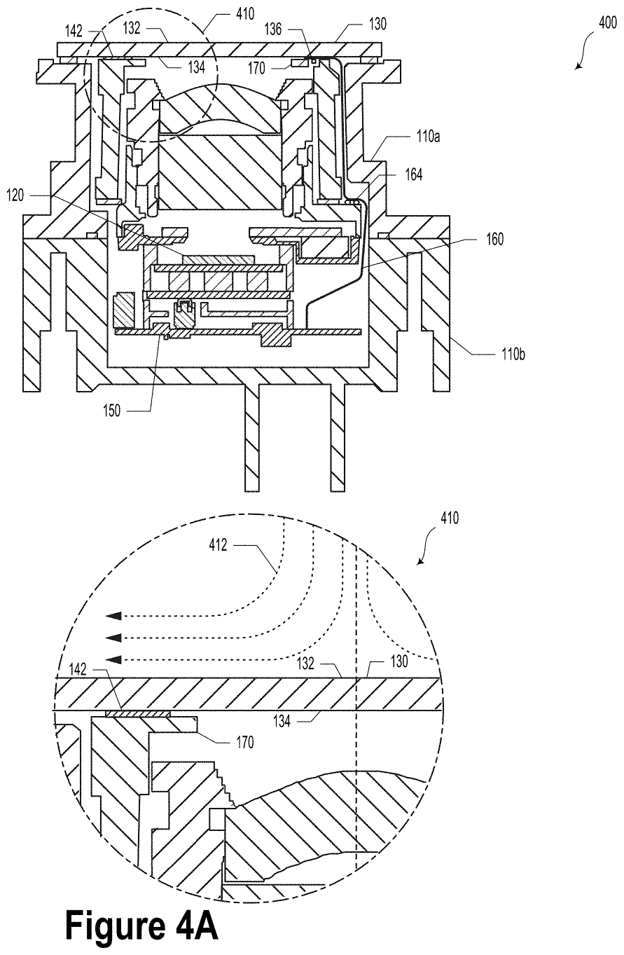

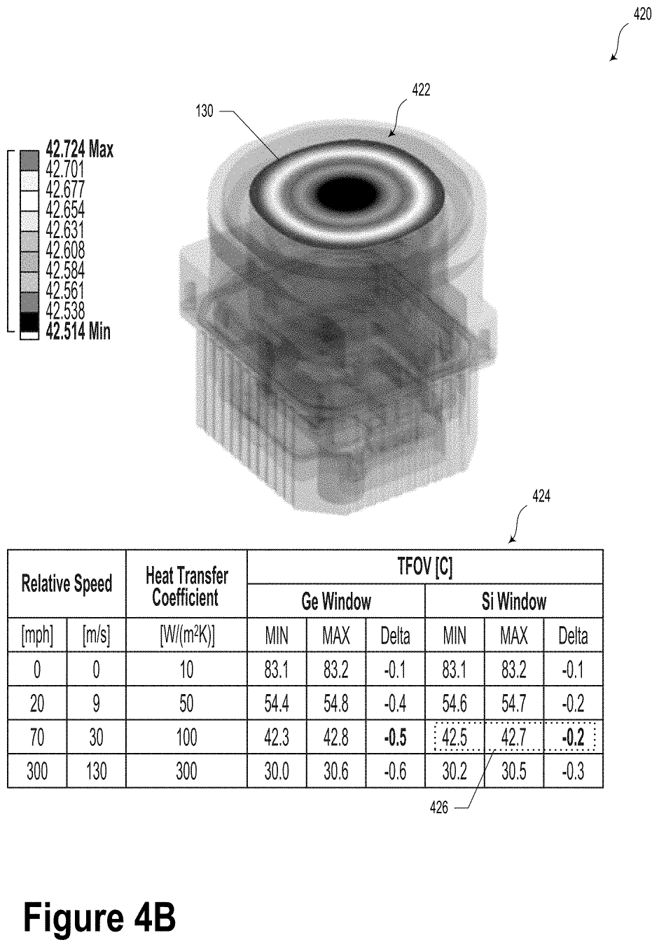

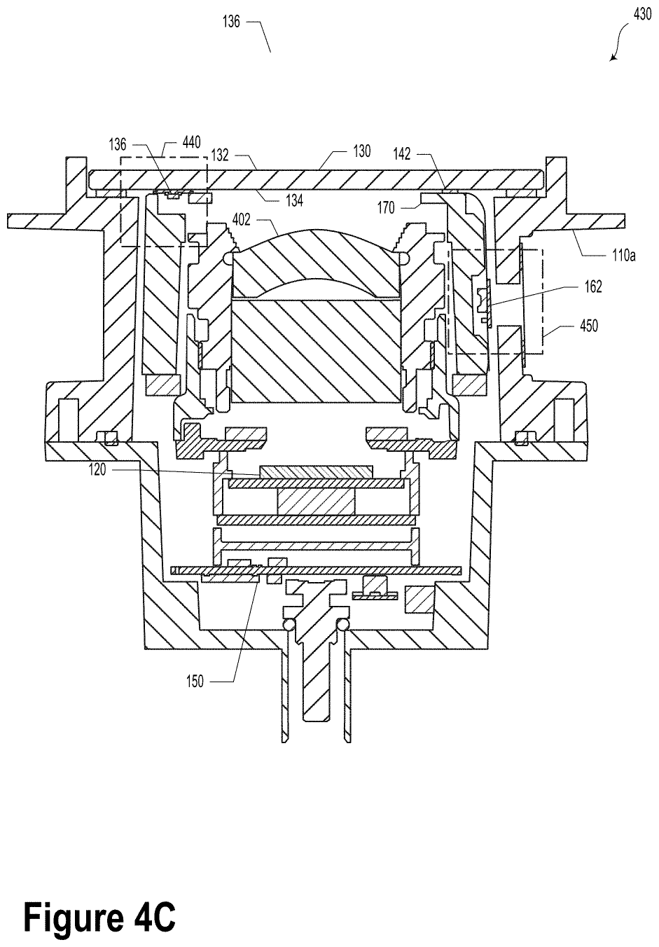

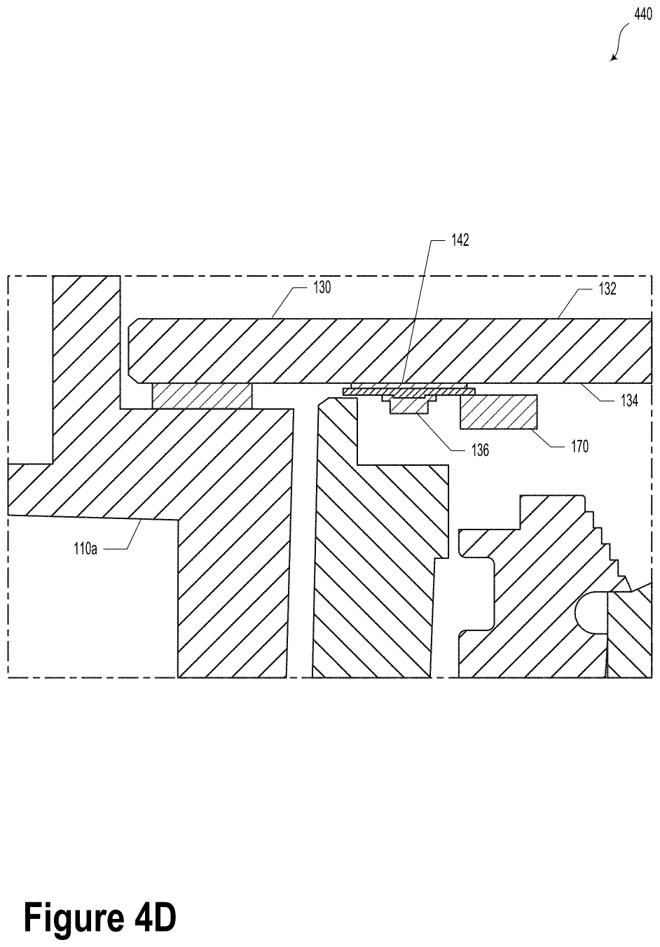

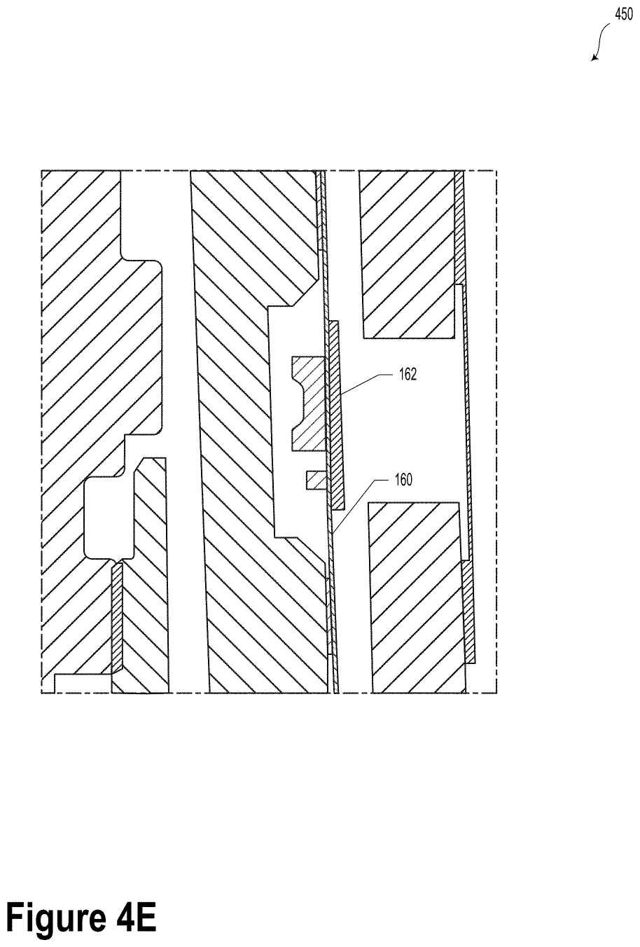

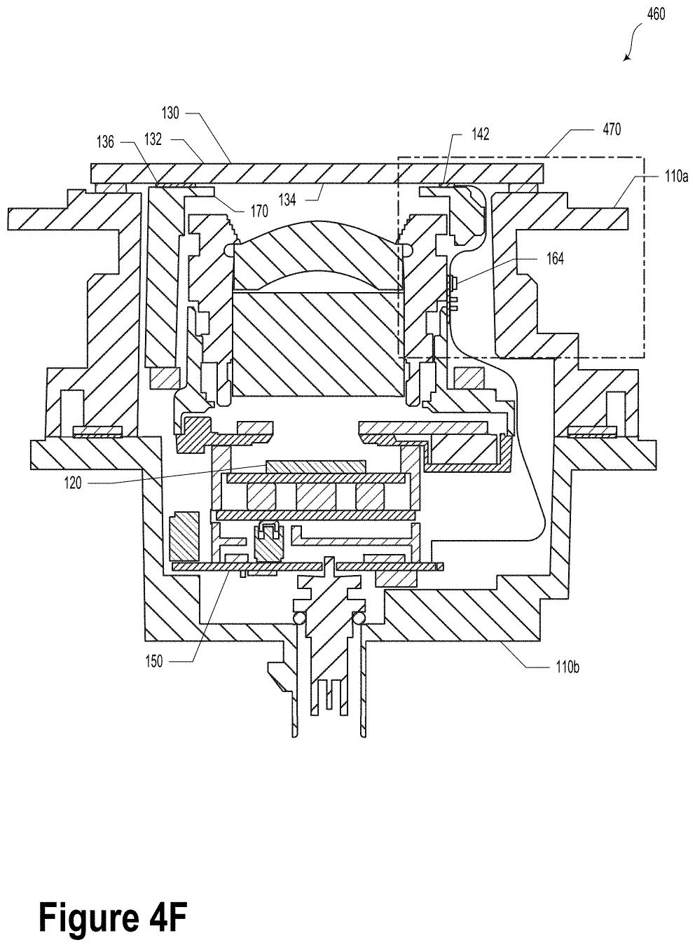

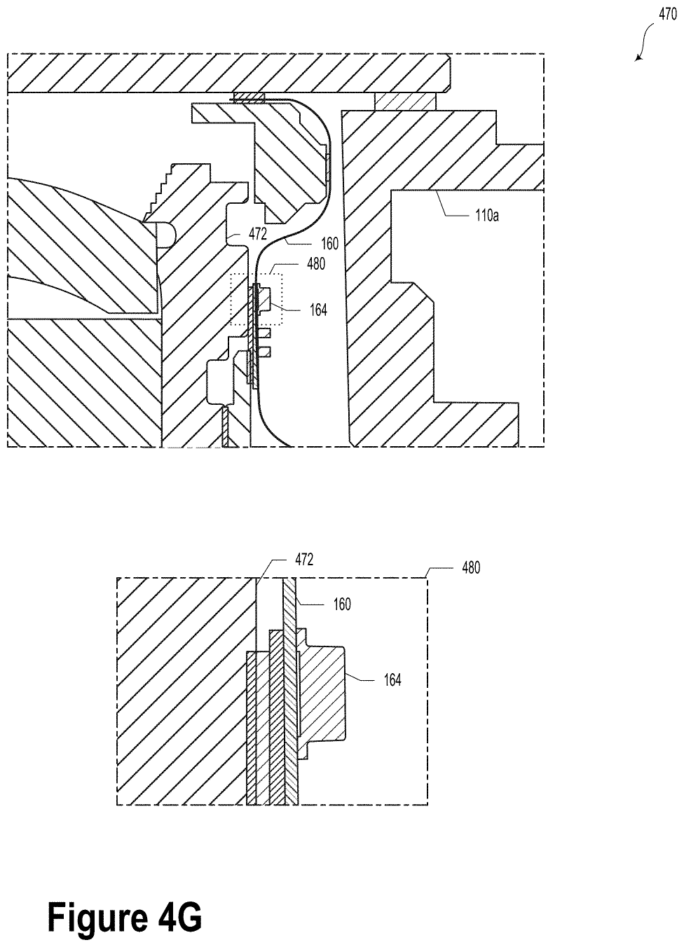

FIG. 4A illustrates several views 400 and 410 of the optical system 100 of FIG. 1, according to an example embodiment. As illustrated in FIG. 4A, for an optical system 100 that is facing a direction of vehicle travel, airflow 412 may be directed toward the edges of the optical window 130.

FIG. 4B illustrates a view 420 of the optical system 100 of FIG. 1 and a table 424, according to an example embodiment. View 420 includes a gradient visualization 422 of location-dependent temperature of the optical window 130. As illustrated, gradient visualization 422 could indicate temperatures between approximately 42.5° C. and 42.7° C. In such a scenario, the gradient visualization 422 could relate to entry 426 of table 424.

As illustrated in FIG. 4B, table 424 could include information about minimum and maximum temperatures along a surface of the optical window 130 for germanium and silicon window materials as well as for various relative speeds of the airflow 412. As illustrated in table 424, a silicon window may provide a lower temperature difference in comparison to a germanium window.

FIG. 4C illustrates a view 430 of the optical system 100 of FIG. 1, according to an example embodiment. FIG. 4D illustrates a portion 440 of the optical system 100 of FIG. 1, according to an example embodiment. FIG. 4E illustrates a portion 450 of the optical system 100 of FIG. 1, according to an example embodiment.

FIG. 4F illustrates a view 460 of the optical system 100 of FIG. 1, according to an example embodiment. FIG. 4G illustrates several views 470 and 480 of portions of the optical system 100 of FIG. 1, according to an example embodiment. While FIGS. 4A, and 4C-4G illustrate various elements of optical system 100 as having particular locations and/or arrangements, it will be understood that other arrangements are possible and contemplated.

### III. Example Vehicles

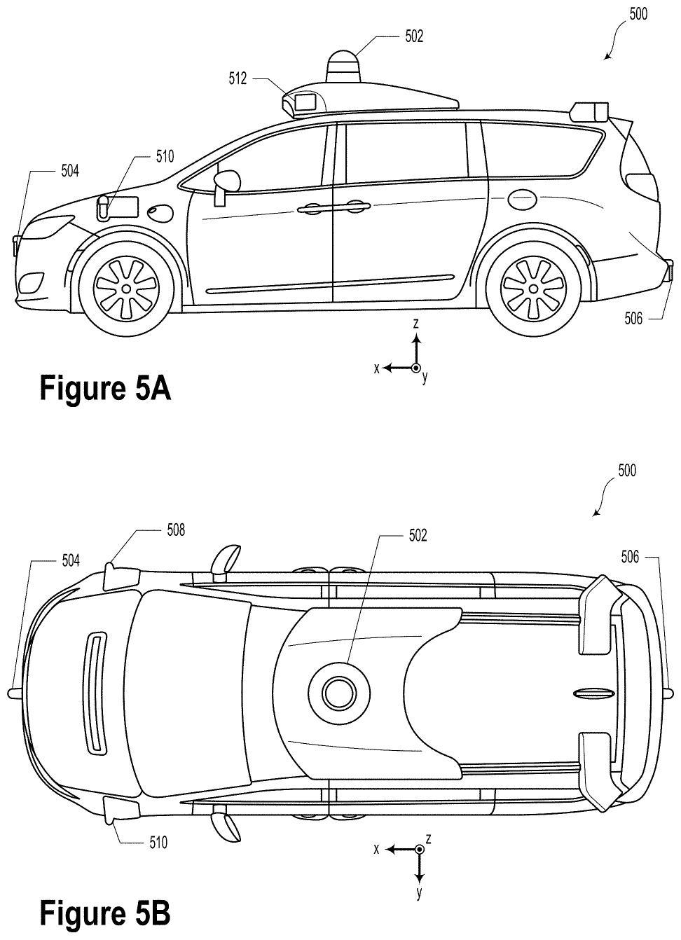

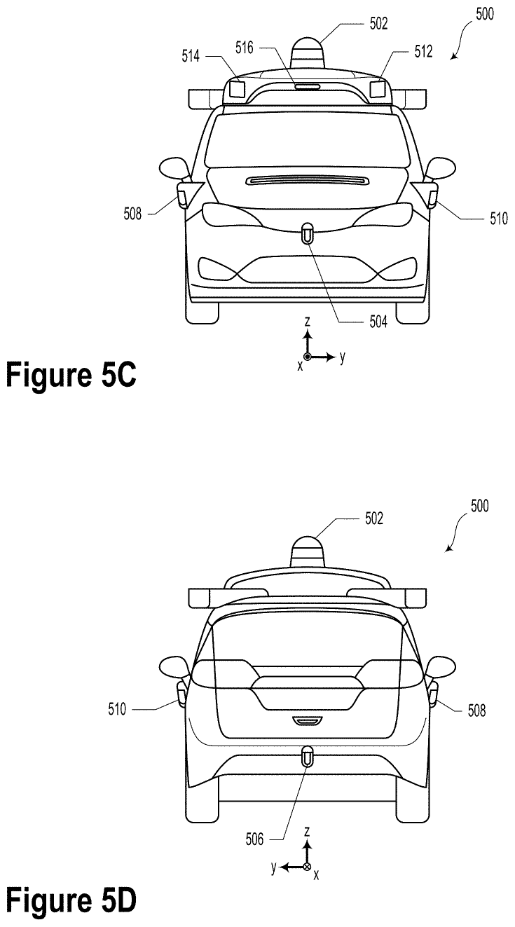

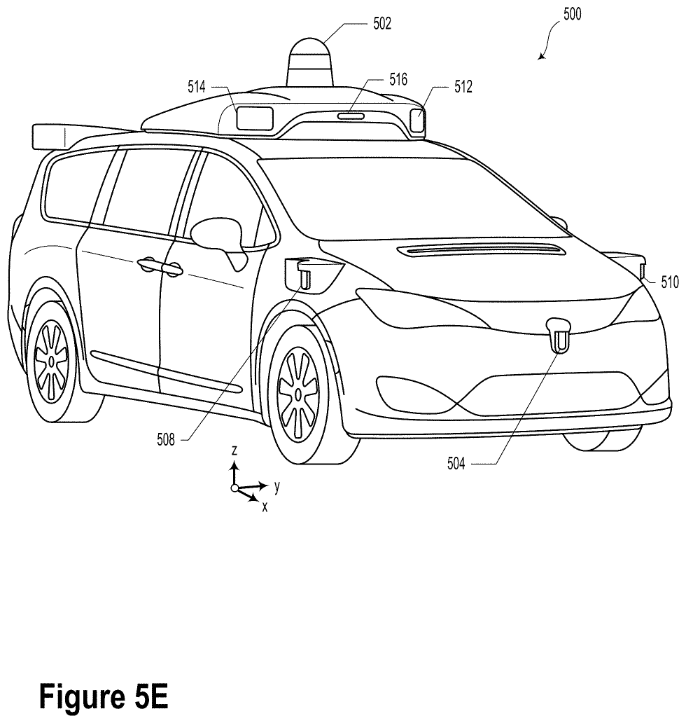

FIGS. 5A, 5B, 5C, 5D, and 5E illustrate a vehicle 500, according to an example embodiment. In some embodiments, the vehicle 500 could be a semi- or fully-autonomous vehicle. While FIGS. 5A, 5B, 5C, 5D, and 5E illustrates vehicle 500 as being an automobile (e.g., a passenger van), it will be understood that vehicle 500 could include another type of autonomous vehicle, robot, or drone that can navigate within its environment using sensors and other information about its environment.

In some examples, the vehicle 500 may include one or more sensor systems 502, 504, 506, 508, 510, and 512. In some embodiments, sensor systems 502, 504, 506, 508, 510, 512, 514, and/or 516 could include optical system 100 as illustrated and described in relation to FIG. 1. In other words, the optical systems described elsewhere herein could be coupled to the vehicle 500 and/or could be utilized in conjunction with various operations of the vehicle 500. As an example, the optical system 100 could be utilized in self-driving or other types of navigation, planning, perception, and/or mapping operations of the vehicle 500.

In some embodiments, one or more sensor systems 502, 504, 506, 508, 510, 512, 514, and/or 516 of vehicle 500 could represent one or more optical systems, such as optical system 100 as illustrated and described in relation to FIGS. 1, 2A-2C, 3A-3B, and 4A-4G. In some examples, the one or more optical systems could be disposed in various locations on the vehicle 500 and could have fields of view that correspond to internal and/or external environments of the vehicle 500.

While the one or more sensor systems 502, 504, 506, 508, 510, 512, 514, and 516 are illustrated on certain locations on vehicle 500, it will be understood that more or fewer sensor systems could be utilized with vehicle 500. Furthermore, the locations of such sensor systems could be adjusted, modified, or otherwise changed as compared to the locations of the sensor systems illustrated in FIGS. 5A, 5B, 5C, 5D, and 5E.

As described, in some embodiments, the one or more sensor systems 502, 504, 506, 508, 510, 512, 514, and/or 516 could include optical system 100, which could include a thermal camera (e.g., thermal camera 120) and other elements of example embodiments described herein. Additionally or alternatively the one or more sensor systems 502, 504, 506, 508, 510, 512, 514, and/or 516 could include lidar sensors. For example, the lidar sensors could include a plurality of light-emitter devices arranged over a range of angles with respect to a given plane (e.g., the x-y plane). For example, one or more of the sensor systems 502, 504, 506, 508, 510, 512, 514, and/or 516 may be configured to rotate about an axis (e.g., the z-axis) perpendicular to the given plane so as to illuminate an environment around the vehicle 500 with light pulses. Based on detecting various aspects of reflected light pulses (e.g., the elapsed time of flight, polarization, intensity, etc.), information about the environment may be determined.

In an example embodiment, sensor systems 502, 504, 506, 508, 510, 512, 514, and/or 516 may be configured to provide respective point cloud information that may relate to physical objects within the environment of the vehicle 500. While vehicle 500 and sensor systems 502, 504, 506, 508, 510, 512, 514, and/or 516 are illustrated as including certain features, it will be understood that other types of sensor systems are contemplated within the scope of the present disclosure.

### IV. Example Methods

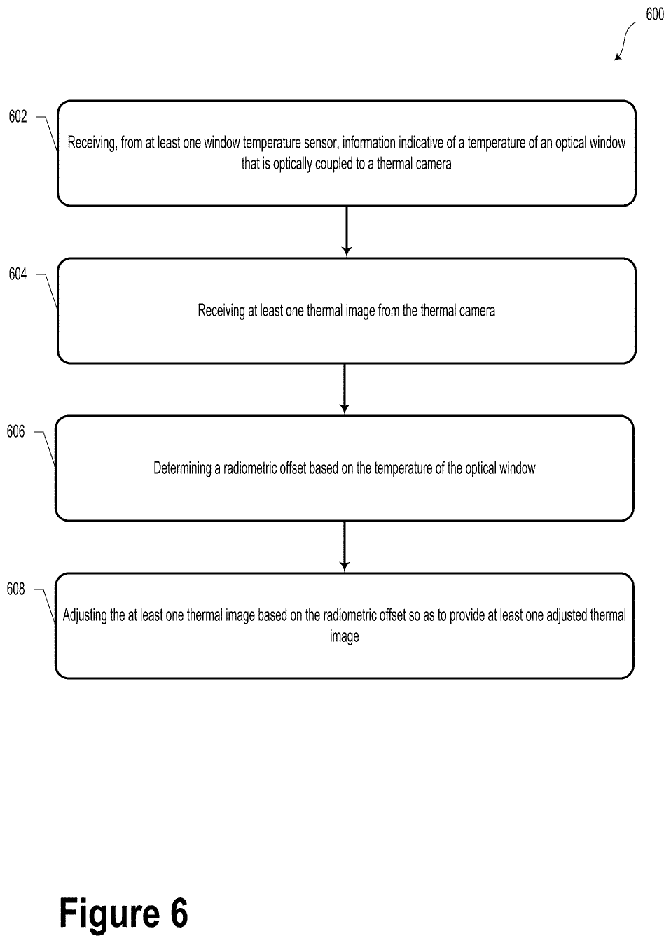

FIG. 6 illustrates a method 600, according to an example embodiment. While method 600 illustrates blocks 602, 604, 606, and 608 of a method, it will be understood that fewer or more blocks or steps could be included. In such scenarios, at least some of the various blocks or steps may be carried out in a different order than of that presented herein. Furthermore, blocks or steps may be added, subtracted, transposed, and/or repeated. Some or all of the blocks or steps of method 600 may be carried out by various elements of optical system 100, such as controller 150, as illustrated and described in reference to FIGS. 1, 2A-C, 3A-B, and 4A-G. Additionally or alternatively, method 600 could be carried out by vehicle 500, as illustrated and described in reference to FIGS. 5A-E.

Block 602 could include receiving, from at least one window temperature sensor (e.g., window temperature sensor 136), information indicative of a temperature of an optical window (e.g., optical window 130) that is optically coupled to a thermal camera (e.g., thermal camera 120). For example, a window temperature sensor could provide information about the temperature of an inner surface of the optical window. It will be understood that the window temperature sensor could include one or more of: an integrated circuit temperature sensor, a thermistor, a thermocouple, a resistance thermometer, and/or a silicon bandgap temperature sensor. Other types of contact and non-contact temperature sensors are possible and contemplated.

Block 604 includes receiving at least one thermal image from the thermal camera. As described herein, the thermal camera could include an image sensor that is configured to detect light in the thermal infrared wavelength range (e.g., light with wavelengths between approximately 7 microns to 14 microns). The thermal camera could include a cooled or uncooled infrared sensor. The infrared sensor could include a thermal detector such as one or more bolometers, microbolometers, thermocouples, thermopiles, Golay cells, and pyroelectric detectors. In other example embodiments, the infrared sensor could include one or more photodetectors formed from materials such as HgCdTe, InSb, InAs, and/or InSe. Other materials are possible and contemplated.

Block 606 includes determining a radiometric offset based on the temperature of the optical window. In some embodiments, determining the radiometric offset could be further based on at least one of: an interior cavity temperature of a housing (e.g., housing 110), an interior cavity humidity of the housing, or a lens body temperature of the thermal camera. In some embodiments, determining the radiometric offset could include utilizing temperature and/or humidity information to estimate the spectral intensity of black-body radiation emitted from internal surfaces of the optical system.

Block 608 includes adjusting the at least one thermal image based on the radiometric offset so as to provide at least one adjusted thermal image. In some embodiments, method 600 could include determining, based on the temperature of the optical window, a temperature gradient (e.g., gradient visualization 422) of the optical window. In such scenarios, determining the radiometric offset could be further based on the temperature gradient of the optical window.

Adjusting the thermal image could include obtaining more accurate image information by subtracting the spectral intensity of the black-body radiation emitted from the internal surfaces of the optical system. In such scenarios, the adjusted thermal image may be clearer and/or provide better disambiguation of objects within the field of view. In some embodiments, the adjusted thermal image could include less noise and/or blur with respect to the initial thermal image.

It will be understood that other ways to adjust the thermal image to provide the adjusted thermal image are possible and contemplated. For example, the spectral black-body radiation could be utilized in other ways to correct defects and/or undesirable aspects of the thermal image. As some examples, the original thermal image could be multiplied, divided, or averaged with respect to the spectral black-body information. The thermal image could be adjusted by way of contract change, brightening, gamma correction, color adjustment, and/or other image adjustments based on the spectral black-body information.

Additionally or alternatively, method 600 could include causing a window heater (e.g., window heater 142) to adjust the temperature of the optical window according to a desired window temperature.

The particular arrangements shown in the Figures should not be viewed as limiting. It should be understood that other embodiments may include more or less of each element shown in a given Figure. Further, some of the illustrated elements may be combined or omitted. Yet further, an illustrative embodiment may include elements that are not illustrated in the Figures.

A step or block that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical functions or actions in the method or technique. The program code and/or related data can be stored on any type of computer readable medium such as a storage device including a disk, hard drive, or other storage medium.

The computer readable medium can also include non-transitory computer readable media such as computer-readable media that store data for short periods of time like register memory, processor cache, and random access memory (RAM). The computer readable media can also include non-transitory computer readable media that store program code and/or data for longer periods of time. Thus, the computer readable media may include secondary or persistent long term storage, like read only memory (ROM), optical or magnetic disks, compact-disc read only memory (CD-ROM), for example. The computer readable media can also be any other volatile or non-volatile storage systems. A computer readable medium can be considered a computer readable storage medium, for example, or a tangible storage device.

While various examples and embodiments have been disclosed, other examples and embodiments will be apparent to those skilled in the art. The various disclosed examples and embodiments are for purposes of illustration and are not intended to be limiting, with the true scope being indicated by the following claims.

1. An optical system comprising:
a housing;
a thermal camera disposed inside the housing;
an optical window coupled to an opening of the housing;
a heater assembly comprising:
a window heater; and
at least one connector extending from the window heater, wherein the window heater is thermally coupled to an inner surface of the optical window, and wherein the window heater is configured to maintain the optical window at a desired temperature; and
a thermal baffle, wherein the thermal baffle is configured to define a field of view of the thermal camera such that the window heater is not within the field of view of the thermal camera, and wherein the thermal baffle comprises a thermally-insulating material.

2. The optical system of claim 1, wherein the window heater comprises:
a pressure-sensitive adhesive (PSA);
a two-layer flexible printed circuit board (flex PCB); and
a stiffener.

3. The optical system of claim 2, wherein at least one of the PSA or the stiffener comprises a thermally-conductive material.

4. The optical system of claim 2, wherein the flex PCB comprises:
at least one heater element; and
at least one window temperature sensor.

5. The optical system of claim 2, wherein the stiffener comprises at least one of: stainless steel, aluminum, or copper.

6. The optical system of claim 1, wherein the thermal baffle comprises one or more protrusions to define the field of view of the thermal camera and prevent light from impinging onto the thermal camera.

7. The optical system of claim 1, wherein the window heater comprises a flat annulus shape having a first surface coupled to the optical window and a second surface coupled to the thermal baffle.

8. The optical system of claim 1, wherein the window heater further comprises an alignment liner configured to assist alignment of the window heater with respect to the optical window.

9. The optical system of claim 1, wherein the heater assembly comprises a flexible material, wherein the flexible material comprises at least one of: polyimide, polyester, polyether ether ketone (PEEK), or flexible silicon.

10. The optical system of claim 1, wherein the optical window comprises at least one of: germanium or silicon.

11. The optical system of claim 1, wherein the at least one connector comprises a first connector comprising an interior sensor, wherein the interior sensor is disposed within an interior cavity of the housing, wherein the interior sensor is configured to provide information indicative of a temperature and a humidity of the interior cavity of the housing.

12. The optical system of claim 11, wherein the at least one connector further comprises a second connector comprising a lens body sensor, wherein the lens body sensor is thermally coupled to a lens body of the thermal camera by way of a thermal interface material, wherein the lens body sensor is configured to provide information indicative of a temperature of the lens body.

13. The optical system of claim 1, further comprising a controller, wherein the controller comprises at least one processor and a memory, wherein the at least one processor is configured to execute instructions stored in the memory so as to carry out operations, the operations comprising:
receiving, from at least one window temperature sensor, information indicative of a temperature of the optical window;
receiving at least one thermal image from the thermal camera;
determining a radiometric offset based on the temperature of the optical window; and
adjusting the at least one thermal image based on the radiometric offset so as to provide at least one adjusted thermal image.

14. The optical system of claim 13, wherein the operations further comprise:
determining, based on the temperature of the optical window, a temperature gradient of the optical window, wherein determining the radiometric offset is further based on the temperature gradient of the optical window.

15. The optical system of claim 13, wherein the operations further comprise:
causing the window heater to adjust the temperature of the optical window according to a desired window temperature.

16. The optical system of claim 13, wherein determining the radiometric offset is further based on at least one of: an interior cavity temperature of the housing, an interior cavity humidity of the housing, or a lens body temperature of the thermal camera.

17. A method, comprising:
receiving, from at least one window temperature sensor, information indicative of a temperature of an optical window that is optically coupled to a thermal camera;
receiving at least one thermal image from the thermal camera;
determining a radiometric offset based on the temperature of the optical window; and
adjusting the at least one thermal image based on the radiometric offset so as to provide at least one adjusted thermal image.

18. The method of claim 17, further comprising:
determining, based on the temperature of the optical window, a temperature gradient of the optical window, wherein determining the radiometric offset is further based on the temperature gradient of the optical window.

19. The method of claim 17, further comprising:
causing a window heater to adjust the temperature of the optical window according to a desired window temperature.

20. The method of claim 17, wherein determining the radiometric offset is further based on at least one of: an interior cavity temperature of a housing, an interior cavity humidity of the housing, or a lens body temperature of the thermal camera.
